(19) United States
(12) Patent Application Publication
(10) Pub. No.: US 2017/0302101 A1
(43) Pub. Date: Oct. 19, 2017

(54) Electronics Charging Station

(71) Applicant: Gregory Varacek, Blue Point, NY (US)

(72) Inventor: Gregory Varacek, Blue Point, NY (US)

(21) Appl. No.: 15/435,191

(22) Filed: Feb. 16, 2017

Related U.S. Application Data
(60) Provisional application No. 62/295,793, filed on Feb. 16, 2016.

(51) Int. Cl. H02J 7/35; H02J 7/00; H02S 20/30; A45B 25/18; A45B 23/00; H01L 31/05

(52) U.S. Cl. CPC H02J 7/35; H02J 7/0045; H02J 7/0027; H01L 31/0504; H02S 20/30; A45B 25/18; A45B 23/00; A45B 2023/0012

(57) ABSTRACT

An electronics charging station for powering and charging an electronic device is provided. The electronics charging station comprises an umbrella. The umbrella comprises a main shaft having a first end and a second end a plurality of ribs extending from the main shaft, and a canopy having a top surface and a bottom surface with the bottom surface of the canopy mounted to the ribs. At least one solar panel is mounted to the top surface of the canopy. At least one rechargeable battery is provided for capturing and storing the energy from the at least one solar panel. An outlet box is electrically connected to the at least one solar panel and the at least one rechargeable battery. Upon connecting the electronic device to the outlet box, the electronic device Is powered and charged.

### CLAIM OF PRIORITY

This patent application claims priority under 35 USC 119 (e) (1) from U.S. Provisional Patent Application Ser. No. 62/295,703 filed Feb. 18, 2016, of common inventorship herewith entitled, “Charging Caddie/” which is incorporated herein by reference as though the same were set forth in its entirety.

### FIELD OF THE INVENTION

The present invention pertains to the field of charging power for electronic batteries, and more specifically to the field of electronics charging stations for charging a variety of electronic devices via solar energy.

### BACKGROUND OF THE INVENTION

One the most explosive technologies in recent years is the cellular telephone. The basic concept of cellular phones began approximately sixty eight years ago when telecommunications researchers sought ways to increase the traffic capacity and frequency of mobile communication in police car radios. Nonexistent technology and stringent federal regulations postponed availability until approximately thirty six years ago, when commercial cellular use was authorized by federal government. As a result of this regulation, the scientific advances of the intervening years and increased competition among communications companies put the cellular telephone on the fast track. Today's widespread use of these revolutionary devices is unsurprising, since they now offer a virtually endless array of benefits.

In addition to serving as a practical means of communication while on the go, technological advances have helped evolve cell phones into minicomputers. Capable of keeping users abreast of the latest stock quotes, providing wireless Internet access, capturing photos and videos, enabling social networking and playing music and games, cellular and digital telephones have become indispensable to millions of people all over the world.

With an increased dependence on cellular telephone technology, it is important to find more practical and convenient ways to use these necessary devices. To have a working phone whenever needed, cellular telephones require constant charging of the instrument's internal battery. To achieve this charging capability, common accessories include an AC adapter charger for use in the home as well as a convenient, portable charging cord that plugs directly into the cigarette lighter bay in a vehicle. As effective as these devices are in achieving their intended purposes, they cannot always be used. For instance, when individuals and families are spending warm summer days vacationing at a beach resort or relaxing by a swimming pool, these outdoor venues are unequipped with a readily accessible power outlet. As a result, many users find that their phones, which were fully charged at the beginning of the day, have quickly depleted throughout the day. Without access to a means of recharging, these users are left with a dead phone which can pose a serious problem in the event of an important business transaction or a personal emergency.

The prior art has put forth several designs for solar charging stations. Among these are:

US Patent Publication 2014/0009103 to Theresa Mary Nita describes a table top, solar powered charging and electricity provided to renewable devices having a shade structure for outdoor use. The invention has a base structure for stabilising the device and for providing one or more compartments for storing items therein and providing a docking station or cellular phone charging station, a shade structure which contains one or more solar cells attached to an outer surface thereof, an attachment arm which connects the base and the shade structure, and various electronic components operative to convert solar energy into electricity.

U.S. Pat. No. 8,497,656 to Matthew N Portis, Jr. and Obadiah Hampton describes a solar umbrella and table apparatus with attached chairs and containing standalone AC power that is generated from solar energy. The apparatus comprises an umbrella having solar collection devices and a table with attached seating chairs. The electrical system of the apparatus converts collected solar energy to an electrical voltage. Batteries store the energy provided by the solar panels. Inverters convert the DC voltage output from the storage batteries to approximately one hundred twenty volts AC. Power outlet terminals are located on the umbrella and table apparatus to allow one hundred twenty voltage AC powered devices to access the output of the sine wave power inverters.

US Patent Publication 2009/0058354 to Soren David Harrison describes solar powered media systems and apparatuses comprising shade structures, solar cells, energy storage devices, electronics and circuitry, docking stations, wireless communications devices, and audio or visual components capable of outputting media content. One aspect of the solar powered media system and apparatus pertains to shade structures, which provide shade for one or more users. Another aspect of the disclosure pertains to energy storage devices, which store electrical energy to power the solar powered media system. Another aspect of the disclosure pertains to docking stations which allow communication and electrical energy transfer between various devices. Another aspect of the disclosure pertains to audio and visual components capable of outputting media content for one or more users. Another aspect of the disclosure pertains to solar cells integrated into or attached to the said shade structure. Ail aspects can be utilized alone or in combination with one another.

None of these prior art references describe the present invention.

### SUMMARY OF THE INVENTION

It is an object of the present invention to provide an umbrella kiosk powered by solar energy that is specifically engineered to enable individuals to recharge their electronic devices at outdoor locations such as beaches, pools, parks, campgrounds and campuses.

The present invention is an electronics charging station for powering and charging an electronic device. The electronics charging station comprises an umbrella. The umbrella comprises a main shaft having a first end and a second end, a plurality of ribs extending from the main shaft, and a canopy having a top surface and a bottom surface with the bottom surface of the canopy mounted to the ribs. At least one solar panel is mounted to the top surface of the canopy. At least one rechargeable battery is provided for capturing and storing the energy from the at least one solar panel. An outlet box is electrically connected to the at least one solar panel and the at least one rechargeable battery. Upon connecting the electronic device to the outlet box, the electronic device is powered and charged.

In addition, the present invention includes a method for powering and charging an electronic device. The method comprises providing an umbrella comprising a main shaft having a first end and a second end, a plurality of ribs extending from the main shaft, and a canopy having a top surface and a bottom surface with the bottom surface of the canopy mounted to the ribs, mounting at least one solar panel to the top surface of the canopy, providing at least one rechargeable battery, capturing and storing the energy from the at least one solar panel in the at least one rechargeable battery, electrically connecting an outlet box to the at least one solar panel and the at least one rechargeable battery, connecting the electronic device to the outlet box. and powering and charging the electronic device.

The present invention further includes an electronics charging station for powering and charging an electronic device. The electronics charging station comprises an umbrella. The umbrella comprises a main shaft having a first end and a second end, a plurality of ribs extending from the main shaft, and a canopy having a top surface and a bottom surface with the bottom surface of the canopy mounted to the ribs At least one solar panel is mounted to the top surface of the canopy with the at least one solar panel being positioned between adjacent ribs. At least one rechargeable battery is provided for capturing and storing the energy from the at least one solar panel. An outlet box is electrically connected to the at least one solar panel and the at least one rechargeable battery with the outlet box mounted to the main shaft and having at least one electrical power outlet and at least one USB charging dock. Upon connecting the electronic device to the outlet box, the electronic device is powered and charged.

### BRIEF DESCRIPTION OF THE DRAWINGS

FIG. 1 is a perspective view illustrating a first embodiment of an electronics charging station, constructed in accordance with the present invention, showing a portable solar powered charging station contained within a shade umbrella and an integrated base table with rolling capability.

FIG. 2 is a another perspective view illustrating the first embodiment of the electronics charging station, constructed in accordance with the present Invention, showing a portable solar powered charging station contained within a shade umbrella and an integrated base table with rolling capability.

FIG. 3 is a perspective view illustrating the first embodiment of electronics charging station, constructed in accordance with the present invention, showing the umbrella rod integrally inserted into a charging component integrally attached to the top of the table and containing plug-in ports for USB and electrical cords.

FIG. 4 is a perspective view illustrating the first embodiment of electronics charging station, constructed in accordance with the present invention, showing a base table with an outlet box containing USB and electrical ports along with a housing component for batteries which are used optionally if solar energy is unavailable.

FIG. 5 is a perspective view illustrating a second embodiment of the electronics charging station, constructed m accordance with the present invention, showing a single shade umbrella arid rod that is insertable into a standard patio table or umbrella stand.

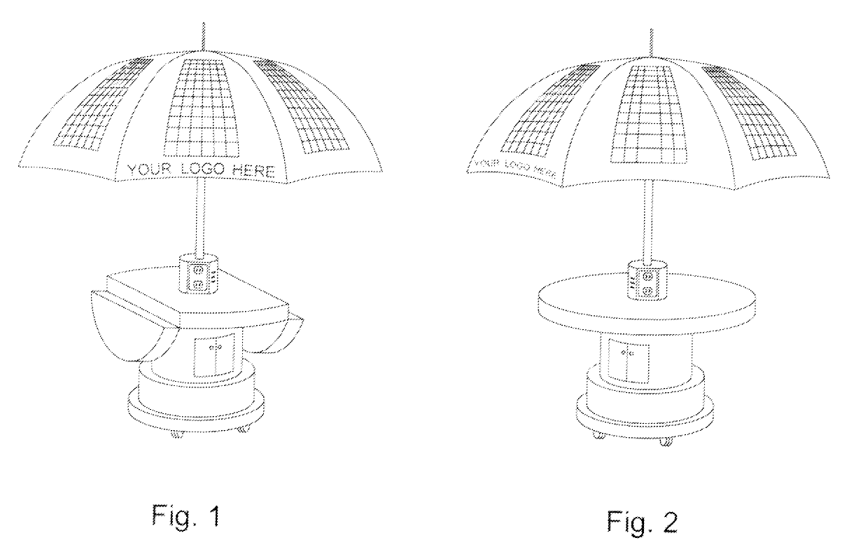

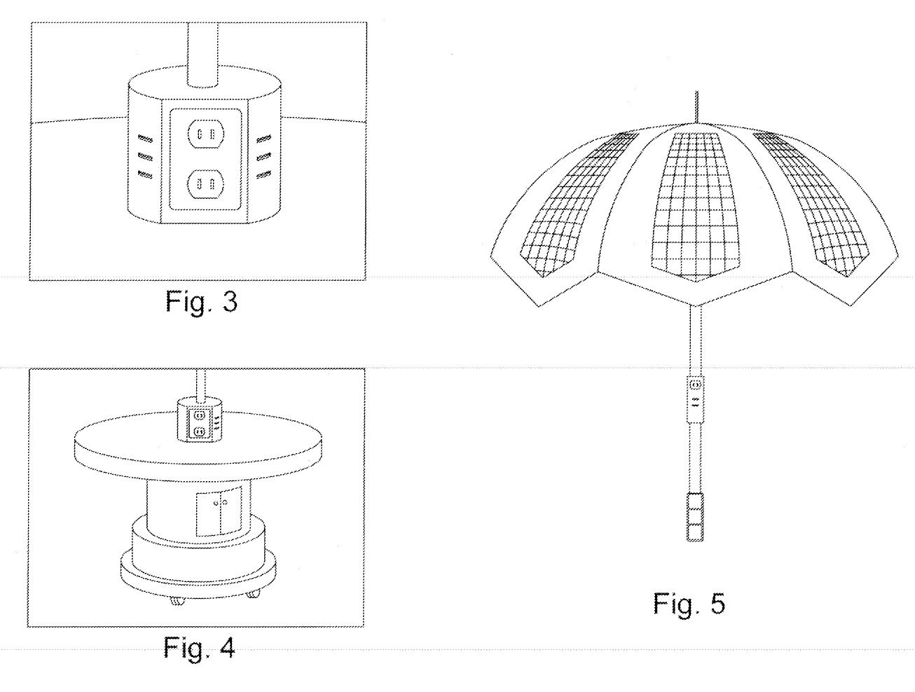

### DETAILED DESCRIPTION OF THE INVENTION

The present invention, hereinafter referred to as an Electronics Charging Station, indicated generally at 10, is a charging kiosk powered by solar energy. The Electronics Charging Station 10 is specifically engineered to enable individuals to recharge their electronic devices at outdoor locations such as beaches, pools, parks, campgrounds, and campuses, The Electronics Charging Station 10 provides an easily accessible means for recharging electronic devices particularly when one is enjoying outdoor activities where power outlets are unavailable.

Portable and self-sustaining, the Electronics Charging Station 10 of the present invention can be constructed in at least two embodiments. The first embodiment of the Electronics Charging Station 10 includes an umbrella 12 having a main shaft 14 and a canopy 16. The main shaft 14 has a first end and a second end. The canopy 16 has a top surface and a bottom surface. A plurality of ribs 18 are mounted at the first end of the main shaft 14 with the bottom surface of the canopy 16 contactingly stretchable over the ribs 18. A plurality of stretchers (not shown) are pivotally mounted between the ribs 18 and a runner (not shown) movable up and down the main shaft 14 from the second end to the first end of the main shaft 14 and from the first end to the second end of the main shaft 14, When the runner is moved up the main shaft 14 toward the first end of the main shaft 14, the runner causes the stretchers to push the ribs 18 in a generally upward direction to stretch the canopy 16 open. A top spring (not shown) nearingly adjacent the first end of the main shaft 14 can releasably maintain the canopy 16 of the umbrella 12 in the open position. Releasing the top spring allows the runner to move down the main shaft 14 toward the second end of the main shaft 14 collapsing the ribs 18 and the canopy 16. A bottom or hand spring (not shown) mounted nearingly adjacent the second end of the main shaft 14 releasably secures the ribs 18 and the canopy 18 in the collapsed position.

While the canopy 16 of the umbrella 12 of the Electronics Charging Station 10 of the present invention has been described as being openable and closable by raising and lowering, respectively, of the runner up and down the main shaft 14, it is within the scope of the present invention for the canopy 16 to be fixedly open without the ability to close the canopy 16, as described above.

The Electronics Charging Station 10 of the present invention includes a series of solar panels 20 incorporated and mounted on the top surface of the canopy 16 of the umbrella 12. The solar panels 20 are exposed for allowing sun rays to provide necessary power to the Electronics Charging Station 10. Preferably, each solar panel 20 is positioned on the top surface of the canopy 18 between adjacent ribs 18 so as not to interfere with the operation of the umbrella 12, as described above. However, it should be noted, that it is within the scope of the present invention for the solar panels 20 to be positioned at any place on the top surface of the canopy 18. including, but not limited, to over the ribs 18.

The solar panels 20 of the Electronics Charging Station 10 of the present invention are preferably standard solar cells in a straightforward application. In operation, a single solar cell produces a maximum of approximately forty five hundredths of a volt and a varying amount of current depending on the size of the cell and the amount of light striking the surface. To maximize the output for the Electronics Charging Station 10, the solar panels 20 require at least four cells wired in series The four cells produce approximately one and eight tenths voltage and a maximum of approximately one hundred milliamps in full sunlight, thus providing enough power for the intended purpose of the Electronics Charging Station 10, as will be discussed further below.

In addition, the Electronics Charging Station 10 of the present invention includes a table station 22 secured, either releasably or otherwise, to the second end of the main shaft 14 of the umbrella 12. The table station 22 has a main housing 24 having a top end and a bottom end. A table top 26 is secured to the top end of the main housing 24 while a plurality of wheels 28 are preferable secured to the bottom end of the main housing 24. Secured within an enclosed area formed in the main housing 24 beneath the table top 26 are the at least one rechargeable battery 29 for capturing and storing the energy from the solar panels 20 and keeping a power supply going even after darkness fails.

The rechargeable battery or batteries 29 of the Electronics Charging Station 10 of the present invention is electrically connected to the solar panels 20 by an electrical wire completely encased within the main shaft 14 of the umbrella 12. partially encased within the main shaft 14 of the umbrella 12, or completely outside the main shaft 14 of the umbrella 12.

The Electronics Charging Station 10 of the present invention further includes an outlet box 30 positioned about the main shaft 14 or near the main shaft 14 nearingly adjacent the center or the second end of the main shaft 14. The outlet box 30 preferably has one or more electrical power outlets 32 and/or USB charging docks 34 electrically connected to both the solar panels 20 and the rechargeable battery or batteries 29. The outlet box 30 is electrically connected to the solar panels 20 and the batteries 29 by an electrical wire completely encased within the main shaft 14 of the umbrella 12, partially encased within the main shaft 14 of the umbrella 12, or completely outside the main shaft 14 of the umbrella 12. When an electronic device is plugged into the appropriate outlet 32 or dock 34 on the outlet box 30, the electronic device can be powered by either the solar panels 20 or the rechargeable battery or batteries 29, depending on the available power supply.

The Electronics Charging Station 10 of the present invention can be wired such that by opening the canopy 16 of the umbrella 12, the solar panels 20 become electrically connected to both the outlet box 30 and the rechargeable battery or batteries 29 within the enclosed area of the main housing 24. Or, in the alternative, the electrical connection between the solar panels 20 and the outlet box 30 and the rechargeable battery or batteries 29 can be maintained even if the canopy 16 is in the close position.

The second embodiment of the Electronics Charging Station 10 of the present Invention is free from the table station 22. The outlet box 30 is mounted directly to the main shaft 14 of the umbrella 12 between the first end and the second end of the main shaft 14. In a preferred embodiment, the outlet box 30 is mounted in the approximate center of the main shaft 14 allowing easy access to the outlet box 30. In addition, the second end of the main shaft 14 of the umbrella 12 is preferably pointed allowing the main shaft 14 to be inserted into the sand or ground, or the second end of the main shaft 14 can be inserted into an existing umbrella stand or patio table engineered for holding a shade umbrella. The rechargeable battery or batteries 29 are mounted within a receiving area 36 within the main shaft 14 and accessible to the user in case of maintenance or replacement.

Extending to a height of approximately six to seven feet, the umbrella of the Electronics Charging Station 10 of the present invention supplies power to the kiosk and provides protection of expensive devices against the elements. The outlet box 30 has a series of AC power outlets 32 and USB charging docks 34 germane to a variety of electronic brands. In the first embodiment, the enclosed area of the table station 22 receives the replaceable batteries 29 and the table station 22 holds the second end of the main shaft 14 of the umbrella 12. In the second embodiment containing only an umbrella 12, the outlet box 30 is mounted directly to the main shaft 14 of the umbrella 12 and the rechargeable batteries 29 are integrally attached with the main shaft 14 of the umbrella 12.

The Electronics Charging Station 10 of the present invention provides cellular telephone subscribers with a simple and effective means of maintaining a fully charged telephone at all times, particularly while relaxing outdoors Stationed in direct sunlight, the Electronics Charging Station 10 begins charging a phone or other electronic device in a matter of seconds. Other electronic devices powerable by the Electronics Charging Station 10 include tablet computers, iPads, iPods, Mp3 players, and virtually any other mobile device with a rechargeable battery. Regardless of its outdoor location, the Electronics Charging Station 10 of the present invention efficiently and expediently can keep electronics powered at all times.

Although this invention has been described with respect to specific embodiments, it is not intended to be limited thereto and various modifications which will become apparent to the person of ordinary skill in the art are intended to fall within the spirit and scope of the invention as described herein taken in conjunction with the accompanying drawings and the appended claims.

1. An electronics charging station for powering and charging an electronic device, the electronics charging station comprising:
an umbrella comprising:
a main shaft having a first end and a second end;
a plurality of ribs extending from the main shaft; and
a canopy having a top surface and a bottom surface, the bottom surface of the canopy mounted to the ribs;
at least one solar panel mounted to the top surface of the canopy;
at least one rechargeable battery for capturing and storing the energy from the at least one solar panel; and
an outlet box electrically connected to the at least one solar panel and the at least one rechargeable battery;
wherein upon connecting the electronic device to the outlet box, the electronic device is powered and charged.

2. The electronics charging station of claim 1 wherein the canopy is openable and closable.

3. The electronics charging station of claim 2 wherein the solar panels electrically disconnect from the at least one rechargeable battery and the outlet box upon closing of the canopy.

4. The electronics charging station of claim 1 wherein the at least one solar panel is positioned between adjacent ribs.

5. The electronics charging station of claim 1 and further comprising:
a plurality of solar panels;
wherein a single solar panel is positioned between a set of adjacent ribs.

6. The electronics charging station of claim 1 wherein each solar panel produces a maximum of approximately forty five hundredths of a volt and a varying amount of current depending on the size of the cell and the amount of light striking the surface.

7. The electronic charging station of claim 6 wherein the at least one solar panel has at least four cells wired in series producing approximately one and eight tenths voltage and a maximum of approximately one hundred milliamps in full sunlight.

8. The electronics charging station of claim 1 and further comprising:
a table station secured to the second end of the main shaft of the umbrella; and
an enclosed area formed in the main housing;
wherein the at least one rechargeable battery is positioned within the enclosed area.

5. The electronics charging station of claim 8 wherein the main housing of the table station has a top end and a bottom end, and further comprising:
a table top secured to the top end of the main housing; and
a plurality of wheels secured to the bottom end of the main housing.

10. The electronics charging station of claim 1 wherein the outlet box is mounted to the main shaft of the umbrella.

11. The electronics charging station of claim 10 wherein the outlet box is mounted In the approximate center of the main shaft.

12. The electronics charging station of claim 1 wherein the outlet box has at least one electrical power outlet and at least one USB charging dock.

13. The electronics charging station of claim 1 wherein the second end of the main shaft of the umbrella is pointed.

14. The electronics charging station of claim 1 wherein the at least one rechargeable battery is mounted within a receiving area formed in the main shaft.

15. A method for powering and charging an electronic device, the method comprising:
providing an umbrella comprising:
a main shaft having a first end and a second end;
a plurality of ribs extending from the main shaft; and
a canopy having a top surface and a bottom surface, the bottom surface of the canopy mounted to the ribs;
mounting at least one solar panel to the top surface of the canopy;
providing at least one rechargeable battery,
capturing and storing the energy from the at least one solar panel in the at least one rechargeable battery;
electrically connecting an outlet box to the at least one solar panel and the at least one rechargeable battery;
connecting the electronic device to the outlet box; and
powering and charging the electronic device.

16. An electronics charging station for powering and charging an electronic device, the electronics charging station comprising:
an umbrella comprising:
a main shaft having a first end and a second end;
a plurality of ribs extending from the main shaft, and
a canopy having a top surface and a bottom surface: the bottom surface of the canopy mounted to the ribs;
at least one solar panel mounted to the top surface of the canopy, the at least one solar panel being positioned between adjacent ribs;
at least one rechargeable battery for capturing and storing the energy from the at least one solar panel; and
an outlet box electrically connected to the at least one solar panel and the at least one rechargeable battery, the outlet box mounted to the main shaft, the outlet box having at least one electrical power outlet and at least one USB charging dock;
wherein upon connecting the electronic device to the outlet box, the electronic device is powered and charged.

17. The electronics charging station of claim 1 wherein the solar panels electrically disconnect from the at least one rechargeable battery and the outlet box upon closing of the canopy.

18. The electronics charging station of claim 16 and further comprising:
a plurality of solar panels;
wherein a single solar panel Is positioned between a set of adjacent ribs.

19. The electronics charging station of claim 16 and further comprising;
a table station secured to the second end of the main shaft of the umbrella., the table station having a top end and a bottom end;
an enclosed area formed in the main housing;
a table top secured to me top end of the main housing; and
a plurality of wheels secured to the bottom end of the main housing.
wherein the at least one rechargeable battery is positioned within the enclosed area.

20. The electronics charging station of claim 16 wherein the at least one rechargeable battery is mounted within a receiving area formed in the main shaft.
